(19) United States
(12) Patent Application Publication
(10) Pub. No.: US 2011/0006874 A1
(43) Pub. Date: Jan. 13, 2011

(54) MICROMECHANICAL ACTUATOR

(75) Inventors: Mike Becker, Bremen (DE); Dietmar Lütke-Notarp, Koln (DE); Klaus Froehner, Stuhr (DE)

Correspondence Address: HENRY M FEIEREISEN, LLC;HENRY M FEIEREISEN, 708 THIRD AVENUE, SUITE 1501, NEW YORK, NY, 10017, US

(73) Assignee: NB Technologies GmbH, Bremen (DE)

(21) Appl. No.: 12/919,618

(22) PCT Filed: Feb. 23, 2009
(86) PCT No.: PCT/DE2009/000236

§ 371 Date: Aug. 26, 2010

(30) Foreign Application Priority Data
Feb. 26, 2008 (DE) 10 2008 011 175.9

(51) Int. Cl. H01H 37/46; H01L 21/302; H02N 10/00

(52) U.S. Cl. 337/382; 438/700; 310/306; 257/E21.214

(57) ABSTRACT

A micromechanical actuator includes a movable first spring element having metal and/or silicon. The first spring element is fitted at a first point and can move freely at a second point. A second spring element connected to the first spring element has silicon and is partially arranged on an electrically insulating material which is applied to a substrate. The second spring element is arranged at a distance from the substrate above the substrate on a first plane, and the first spring element is arranged above the second spring element on a second plane which is at a distance from the first plane such that the first and second spring elements can move with respect to the substrate. The actuator has a third spring element which is mechanically coupled to the first spring element. The elastic deformation of the second spring element can be induced by a length change of the third spring element.

The invention relates to a micromechanical actuator as a micro-electrical-mechanical system (MEMS), and to a method for its production. The invention also relates to the use of the actuator as an electrical switch which is arranged on a substrate, for example composed of silicon. A switch such as this is referred to in the following text as a microswitch.

An MEMS may have very small dimensions down to a few 100 μm. The moving mechanical structures and structural elements are produced very economically by the known methods and apparatuses in the semiconductor industry. These include, in particular, photolithographic processes as well as sputtering, vapor deposition, etching of all types, stripping, printing and electroplating. Further applications of an MEMS are, for example, sensors, transmissions and valves.

The invention will be described in the following text using the example of thermally actuated electrical microswitches by means of two actuators, in the form of MEMS. However, it is suitable for all other applications of MEMS which have a mechanical spring element as the moving structural element. The moving elements can be actuated not only by thermal expansion but also, for example, by magnetic, piezoelectric, magnetostrictive or electrostatic force.

The document U.S. Pat. No. 7,036,312 B2 describes a typical MEMS, which is partially mounted on a substrate. Two elongated actuators form an arrangement as a microswitch. Each actuator consists of a so-called hot arm and a cold arm. The respective end of the two arms is firmly anchored to the substrate on an electrically insulating layer. At the other, moving end, the two arms are firmly connected to one another by means of an insulating material. A metallic heating loop is located on the hot arm, consisting of a forward conductor and a return conductor which is electrically insulated from it, starting from the anchor point and leading back to the other anchor point. The heating loop is used for thermal actuation of the actuator. For this purpose, an electrical voltage or constant current is applied briefly to, or impressed on, the two anchor points, to the connecting surfaces located there or to so-called pads of the heating loop. The resistive heat produced by the electric current leads to an increase in the mechanical length of the hot arm. The difference between the lengths of the hot and cold arms which occurs during this process leads to a diverging movement of the two arms, which are firmly connected at the end, in this area, to be precise in the direction from the hot arm to the cold arm. The extent of the diverging movement on an approximately circular path is a multiple of the length change of the hot arm, or the difference between the length changes of the two arms. This diverging movement is a maximum if a bearing were to be located as a rotation point in the area of the anchor point of the cold arm. However, there would then be no restoring force acting on the cold arm when the actuation is switched off. The cold arm is therefore designed such that its cross section tapers significantly, that is to say its width tapers, in the vicinity of its anchor point. This can also be produced without any additional process steps, in comparison to a bearing. The dimensions of the cross section of the taper and its length at the same time govern the respectively effective flexibility and restoring force of the cold arm. This flexible taper is also referred to in the following text as a flexer.

Two such actuators are arranged such that they form an electrical microswitch, wherein the signal current to be switched flows via the cold arms of the actuators. The cold arms are therefore composed of metal. The two actuators and their switching contacts, which are located at the moving end, are arranged and designed such that only one actuating switching pulse with a time in the order of magnitude of about 10 milliseconds is required for each actuator, for the microswitch to change between the ON and OFF switching states. Because of the low thermal capacity of the heating loop, both the heating up and cooling down take place very quickly. In the ON switching state, the two switching contacts are hooked to one another, with the actuation, that is to say the thermal excitation, being switched off. Therefore, overall, a microswitch based on an MEMS such as this requires only a very small amount of excitation energy.

A specific minimum contact force is required in order to achieve a reliable electrical contact. This is applied by the restoring force of at least one of the two actuators. The restoring force is governed virtually exclusively by the material characteristics of the flexer and its dimensions. The cold arm, and therefore also the flexer, consist of an electrically conductive material, for example nickel.

It is known that metals which are subject to a mechanical stress have a tendency to so-called creepage, that is to say they are deformed plastically. In the case of a microswitch having an actuator according to U.S. Pat. No. 7,036,312 B2, which is in the ON switching state for a relatively long time, the effective contact force therefore continuously decreases. Particularly in the case of MEMS as microswitches, this disadvantageous effect is observed even in a short time, for example after a few switching processes, or after a few months when in the ON switching state all the time.

In order to avoid plastic deformation or creepage of the metals used, in particular nickel, as a result of the mechanical stress, it is possible to use an alloy or a mixture of nickel with very small proportions of manganese, iron or cobalt in order to electrochemically produce the arms, and therefore the flexer. Such alloys or mixtures make it possible, in comparison to pure nickel, to stabilize the grain structure, in particular at relatively high temperatures, and to achieve a reduced tendency to plastic deformation. However, this has the disadvantage that it is dependent on the metals to be used and their precise alloying proportions. The characteristics when loaded in the long term are unknown.

The heating loop is mechanically coupled to the cold arm by electrically insulating holders. The holders are then arranged at a number of points in the longitudinal direction of the actuators, and are attached to the hot and cold arms. The holders allow maximum utilization of the length change for transmission to the cold arm, in that divergent strain at right angles to the length expansion of the heating loop is prevented. In order to achieve the maximum possible length extension of the heating loop, this can also be arranged movably in the holders. In consequence, the thermally actuating force acts only on the moving end of the actuator on the cold arm. The problem of plastic deformation of metals as described above, and therefore the decreasing restoring force of the spring effect of the flexer cannot, however, be solved even in an arrangement such as this.

One object of the invention is to propose a micromechanical actuator which has at least one spring element which may be permanently subjected to mechanical stress and in the process has mechanical characteristics which are stable in the long term, and in which case different materials, particularly metals, can be used for an electrically conductive structural element. A further aim is to be able to produce the actuator using known methods.

The object is achieved by a micromechanical actuator as claimed in independent patent claim 1 and by a method for its production as claimed in patent claim 19. Advantageous embodiments of the invention are the subject matter of the dependent claims.

The actuator according to the invention uses the long-term-stable mechanical characteristics of a material which has silicon for the second spring element on the cold arm, which is referred to as the first spring element.

In order to achieve good electrical conductivity, the first spring element has metal, when this first spring element is also used to carry a signal current. Otherwise, the first spring element of the actuator may partially or completely have silicon or some other material with similar material characteristics, for example glass, ceramic, plastic.

According to the invention, the second spring element has silicon, which may be polycrystalline or monocrystalline silicon. According to one embodiment of the invention, a metallic element can be arranged at a distance from the second spring element and is connected to the first spring element such that an electric current can be transported through the metallic element from one anchor point to another anchor point which is arranged on the first spring element. The current can therefore pass through a bypass formed in this way to the first spring element, and need not pass through the second spring element, which has silicon and has a higher electrical resistance than metal. In contrast, the silicon in the second spring element contributes to the second spring element having characteristics resulting in mechanical behavior which is stable in the long term. The metallic element is particularly advantageous when the intention is to pass a signal current via the first spring element to an electrical contact point which is arranged thereon and is intended for mechanical switching of a contact.

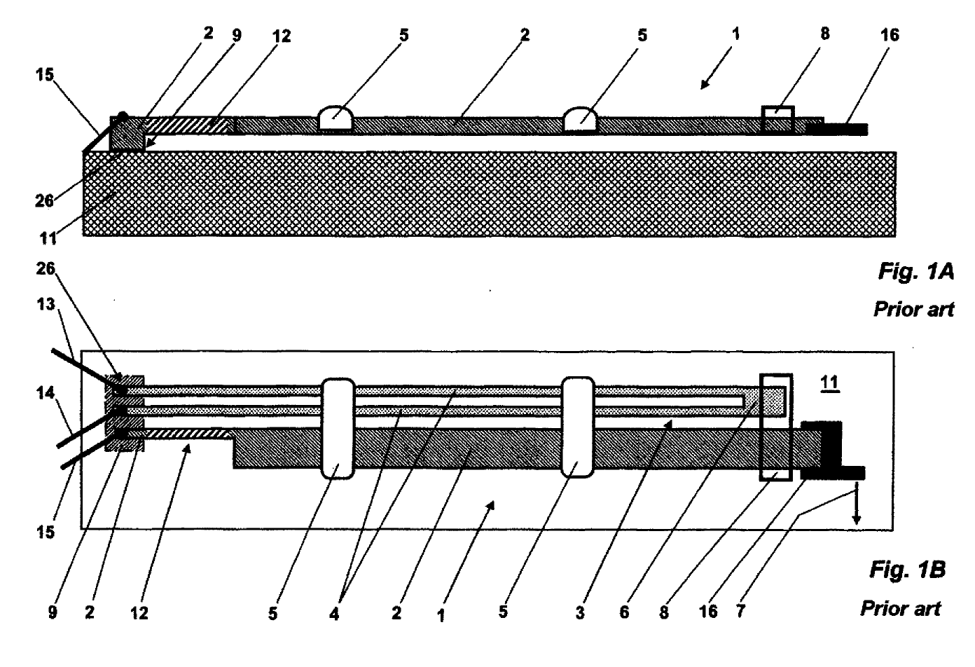

The invention will be described in detail in the following text with reference to the schematic FIGS. 1 to 8, which are not to scale, and in which:

FIG. 1A shows a side view of a micromechanical actuator with thermal actuation according to the prior art;

FIG. 1B shows a plan view of a micromechanical actuator with thermal actuation according to the prior art;

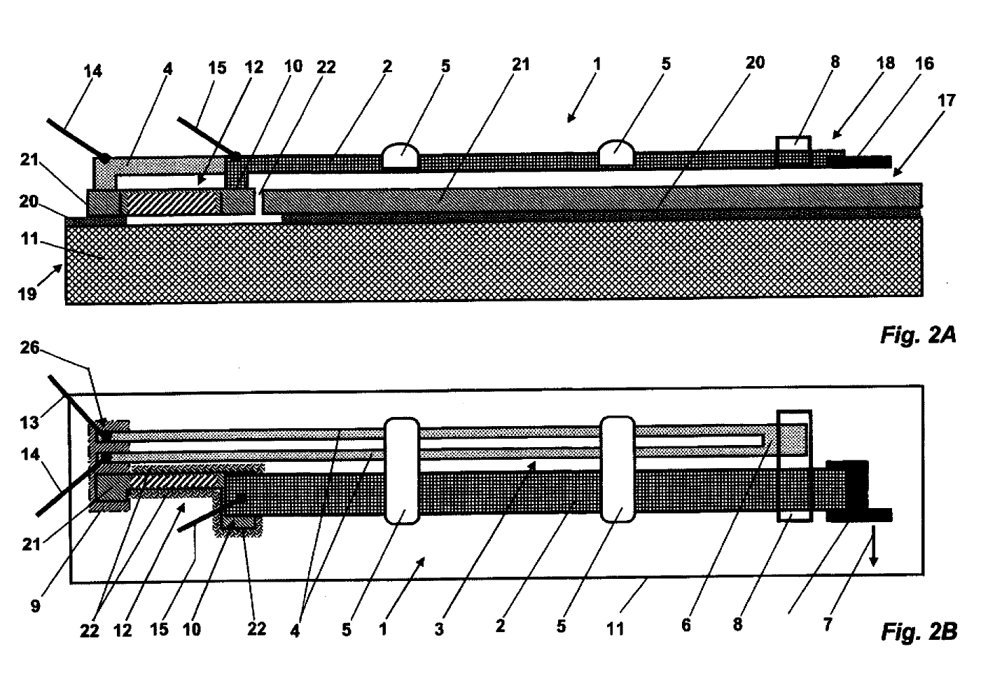

FIG. 2A shows a side view of a micromechanical actuator with thermal actuation according to a first embodiment of the invention;

FIG. 2B shows a plan view of a micromechanical actuator with thermal actuation according to the first embodiment of the invention;

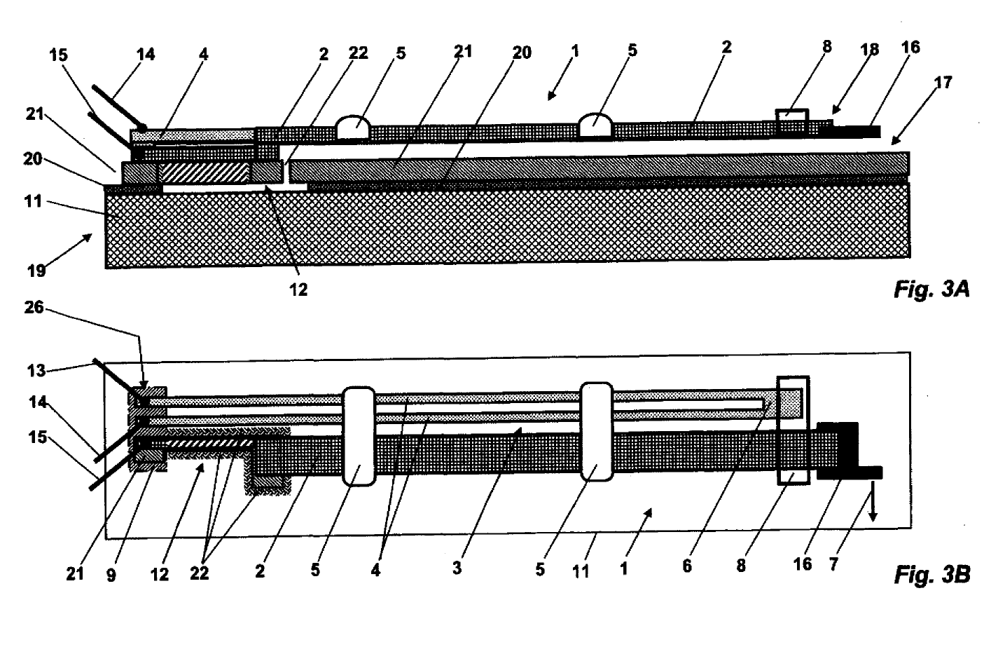

FIG. 3A shows a side view of a micromechanical actuator with thermal actuation according to a second embodiment of the invention;

FIG. 3B shows a plan view of a micromechanical actuator with thermal actuation according to the second embodiment of the invention;

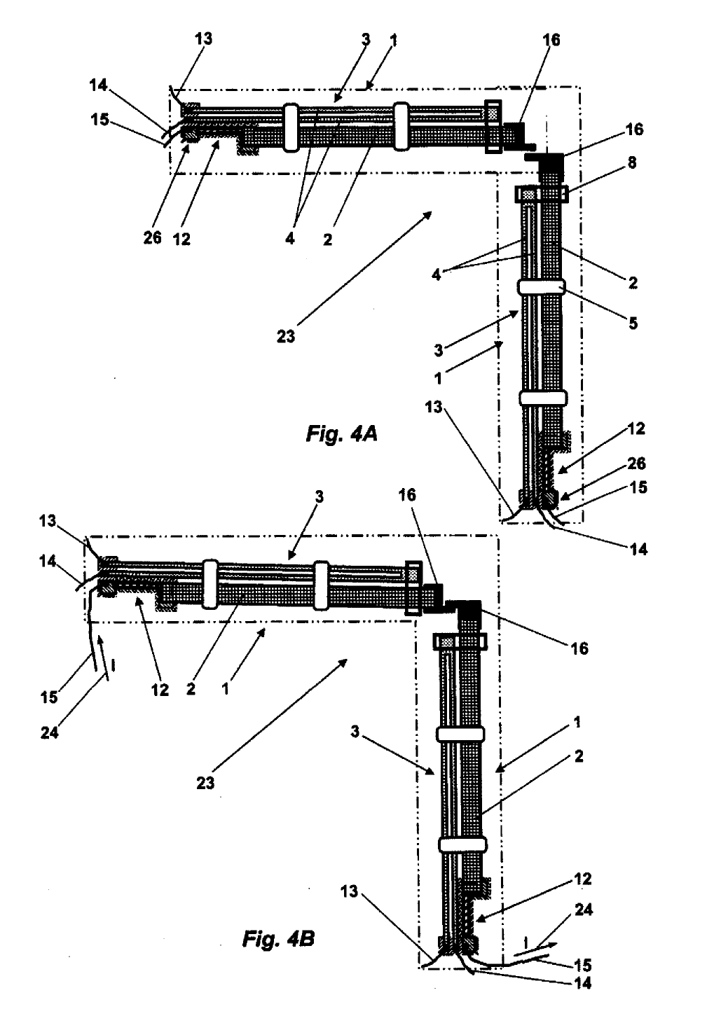

FIG. 4A shows two actuators according to the first embodiment, which are arranged together as a microswitch and are in the OFF switching state;

FIG. 4B shows two actuators according to the first embodiment, which are arranged together as a microswitch and are in the ON switching state;

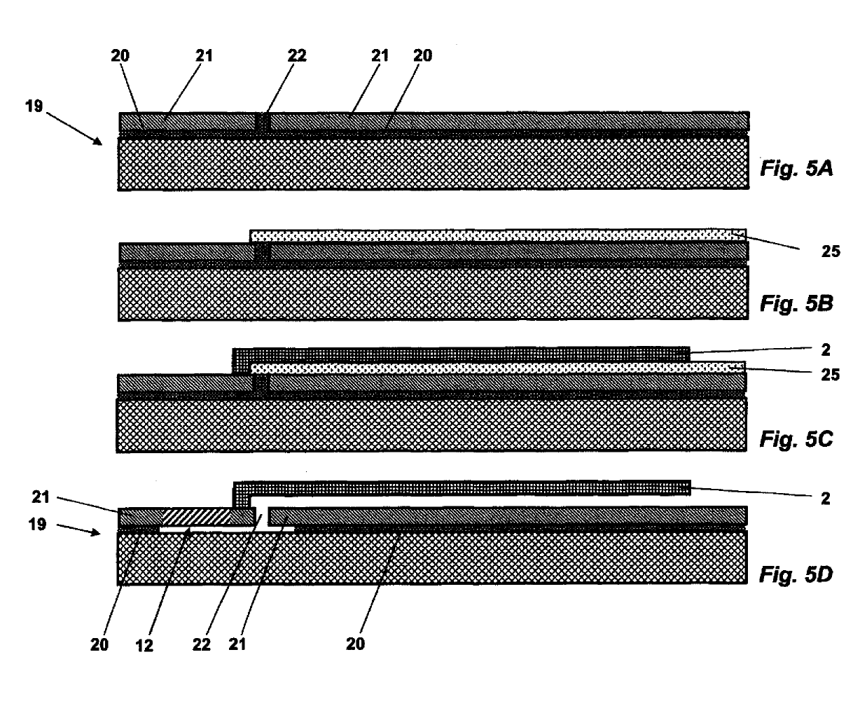

FIGS. 5A to 5D show individual steps in a method according to a first embodiment of the invention for producing the actuator;

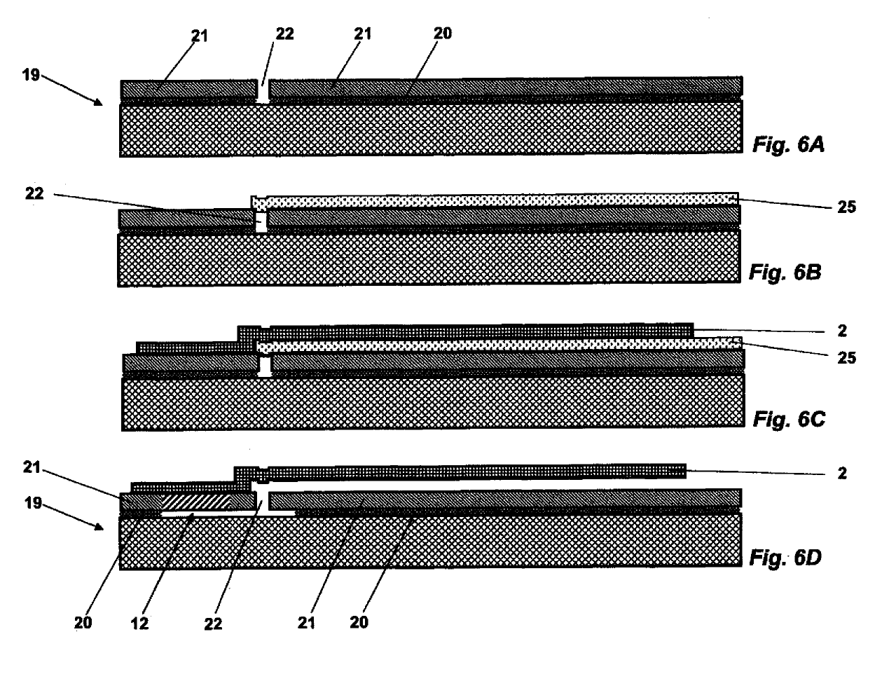

FIGS. 6A to 6D show individual steps in the method according to a second embodiment of the invention for producing the actuator;

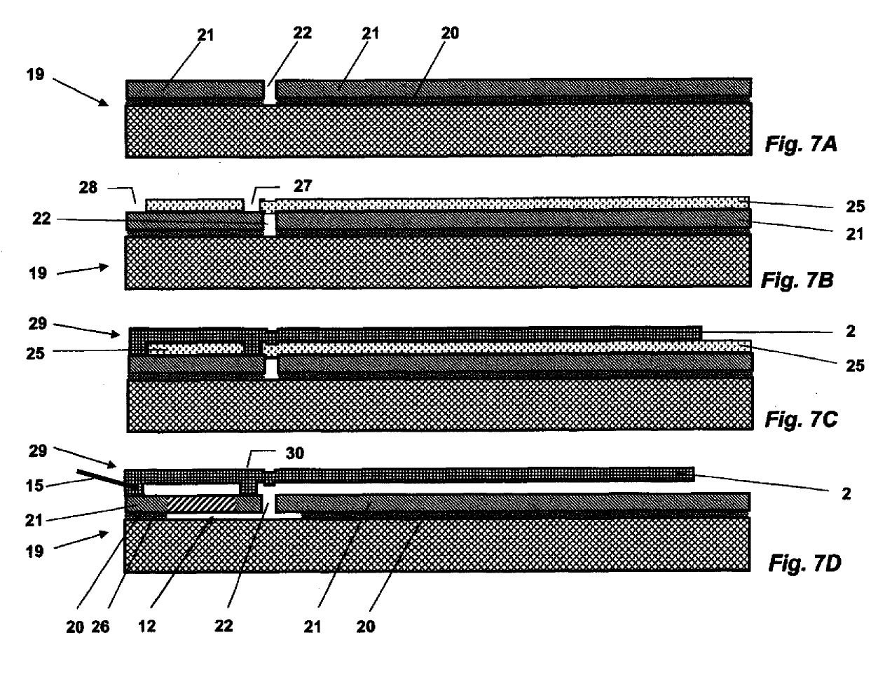

FIGS. 7A to 7D show individual steps in the method according to a third embodiment of the invention for producing the actuator;

FIG. 8 shows a side view of an actuator according to a fourth embodiment of the invention; and

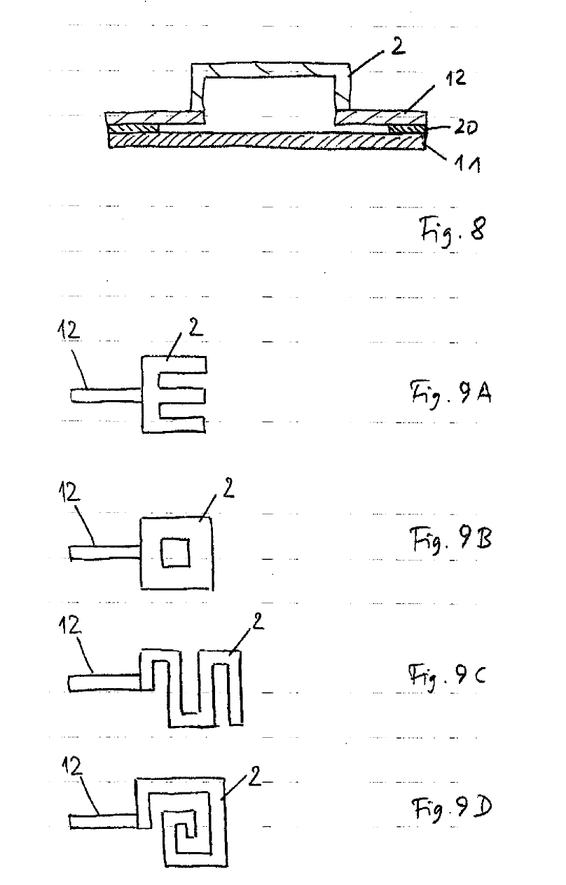

FIGS. 9A to 9D each show a plan view of further embodiments of an actuator according to the invention.

FIGS. 1A and 1B show a microelectrical actuator with thermal actuation according to the prior art. This actuator 1 is produced on a single plane outside and/or above a substrate 11. The substrate 11 is generally a wafer composed of silicon. In this case, production can take place together with the production of the further structures, for example of electrical conductors and semiconductor components on the substrate. The actuator 1 essentially comprises a metallic so-called cold arm 2 and a so-called hot arm 3, which is formed by a heating loop 4 composed of metal. The two arms 2, 3 as well as the two electrical conductors of the heating loop 4 are arranged electrically isolated from one another, and are held mechanically on one another by means of holders 5. The holders 5 are composed of an insulating material, for example of a structured and cured photoresist. The heating loop 4 can be held captive, or can be guided such that it can move longitudinally, in these holders 5. The movement capability means that the length expansion which occurs on thermal actuation will act completely on the reversal point 6 of the heating loop 4, thus achieving maximum deflection 7 of the actuator 1 in the direction of the arrow. For this purpose, the end of the heating loop 4 is firmly connected at its reversal point 6 to the end of the cold arm 2 by means of a further holder, which is referred to in the following text as the end holder 8. The end holder 8 is likewise composed of an electrically insulating material, for example of the same material as the other holders 5. In order to make the illustration clear, this end holder 8 is illustrated as being transparent in all the FIGS. The forward conductor and return conductor of the heating loop 4, as well as the cold arm 2, are firmly connected to the substrate 11 at individual anchor points 10 in the anchor area 9, which is shown in a shaded form. Outside the anchor area 9, the cold arm 2 and the hot arm 3 can move freely parallel to the surface of the substrate 11, and are therefore also electrically isolated from the substrate 11 in this area. This is shown in the side view illustrated in FIG. 1A.

In the vicinity of its anchor point 26, the cold arm 2 is made elastic by means of a taper. This results in the desired large deflection 7 of the actuator 1, which is a multiple of the length expansion of the heating loop 4. However, this small area of the flexer 12, which is illustrated by +45° shading in FIGS. 1A and 1B, is subject to a particularly high mechanical stress when the actuator 1 is thermally actuated. This is essentially a bending stress. When the actuation is switched off, the bending stress must be sufficiently great that the actuator 1 returns to its initial position, or that the required contact force is applied for an electrical contact in a microswitch. When the actuator 1 is being used in practice, the area of the taper 12 accordingly acts as a mechanical spring element.

When the heating loop 4 cools down, it returns to its original length, and therefore to the original position. Because it is firmly connected by the end holder 8 to the cold arm 2, the tensile force of the heating loop 4 assists the return movement of the actuator 1 when the actuation is switched off. When the microswitch is in the ON switching state, at least one of the two actuators 1 does not return to the initial position. The spring force of the flexer 12 and the supporting tensile force of the heating loop 4 apply the contact force of the microswitch, as a result of which both structural elements are subject to a permanent mechanical stress. This results in the disruptive plastic deformation of the metals that are used.

The electrical connections are represented symbolically as conductors 13, 14 and 15 in FIG. 1. These conductors are generally in the form of integrated conductor tracks on the wafer. Known semiconductor technology means and methods are used for this purpose, as for the entire production of the MEMS and of the actuator 1 as well. The conductors 13 and 14 are used to feed the actuating current into the forward conductor and return conductor of the heating loop 4. The conductor 15 carries an electrical signal, to be switched, of the microswitch. There is preferably an electrical switching contact 16 at the other end of the cold arm 2. A contact pair for a microswitch is formed by a similarly shaped mating contact on a further actuator.

The metallic structural elements of the actuator are generally produced electrochemically, for example from nickel. The flexer 12, the rest of the area of the cold arm 2 and the heating loop 4 are therefore also composed of this material. In general, in the case of metals, in particular in the case of electrochemically produced elements, the described metal creepage generally occurs when subjected to permanent mechanical loading, in the form of bending, tensile or compressive stress. This results in plastic deformation, as a result of which the elasticity decreases. In the case of a microswitch, this means a continuously decreasing contact force, thus adversely affecting the reliability, in a disadvantageous manner. This plastic deformation particularly affects the flexer 12, which has to absorb the greatest bending stress over a short length and with a small cross section. The mechanical characteristics of the flexer 12 are therefore particularly and exclusively critical for the long-term stability, for example, of a microswitch formed by actuators.

FIGS. 2A and 2B show a first embodiment of an actuator 1 according to the invention, which does not have the described disadvantages of the prior art. Known semiconductor technology methods are likewise used to produce the actuator 1, for example resist application, photolithographic processes, exposure, stripping, etching, sputtering and electroplating. These widely used processes will therefore not be described in detail in order to explain the invention. The description and the patent claims are restricted to the sequence of the special method steps according to the invention.

The actuator 1 essentially consists of a first spring element 2 and a second spring element 12, with the second spring element 12 being referred to as a flexer. The spring elements 2 and 12 are preferably deflected by a third spring element 3. In the embodiment illustrated in FIGS. 2A and 2B, the third spring element 3 is in the form of a heating loop 4 composed of metal, as has been described in the prior art as shown in FIG. 1. The first spring element 2 has metal and/or silicon. The two spring elements 2, 12 are arranged electrically isolated from one another by the two electrical conductors of the heating loop 4 in the third spring element 3, and are mechanically connected to one another by means of holders 5. The holders 5 are composed of an insulating material, for example of a structured and cured photoresist, epoxy such as SU8 or polymer such as polyimide.

Actuation takes place by means of at least one heating loop 4 for thermal expansion of at least one part of the spring element 3 and by thermal expansion to a different extent of at least one part of the spring elements 2, 12 with respect to at least one part of the spring element 3.

It has been established that silicon is very suitable for use as the material for the flexer 12. It has the required long-term stability even when subjected to a mechanical stress. Unlike metals, silicon does not tend to creep mechanically under load, but retains the elastic characteristics to the failure limit. Monocrystalline silicon can be particularly preferred since, in this case, no grain changes can occur either, and the material is not subject to mechanical stress, because of the undisturbed lattice arrangement. Because silicon is widely used in semiconductor technology, no new processes or substrates are required to produce the actuators according to the invention. The actuators can therefore also be produced highly cost-effectively. SOI wafers (Silicon On Insulator) are preferably used as the raw material for this purpose. A monocrystalline silicon layer, an SOI layer in the following text, is located fixed by adhesive on a thermally produced oxide layer on a wafer composed of silicon. It is known that specific areas of the SOI layer can be exposed by underetching the buried oxide, and can be separated from the layer located underneath, thus creating moving structures. These substrates and processes are used and applied in order to produce the flexer 12 according to the invention. The invention will therefore be described using examples with SOI wafers. However, the invention can also be implemented by means of other substrates and by processes other than this. In this case, other composite substrates may be used, which provide suitable material combinations, and in which an intermediate layer can be removed selectively after structuring of the layer located above it in order to produce moving areas by means of underetching. According to the invention, the intermediate layer is composed of an electrically insulating material, as a result of which elements can be electrically separated by structuring in the uppermost layer.

According to a first embodiment, the actuator 1 according to the invention is formed on two planes 17, 18. The first plane 17 is a part of the composite substrate, and the second plane 18 is located outside the composite substrate. The flexer 12 is arranged on the first plane 17, in the SOI layer 21. This has silicon, which also has no creepage tendency even in the case of SOI wafers when subjected to permanent mechanical stress, that is to say there is no tendency to plastic deformation.

FIGS. 2A and 2B show the SOI wafer 19 which consists of the substrate 11, the oxide layer 20 and the SOI layer 21 located on it. The substrate 11 has silicon. The oxide layer 20 has, for example, silicon oxide, although a nitride or a plastic, polymer, epoxy or lacquer can also be used as an intermediate layer for composite substrates. All the layers are firmly connected to one another. SOI wafers such as these are known and are commercially available.

The outlines of the flexer 12 in the SOI layer 21 are defined by etching narrow trenches 22 in this layer. The three-sided trenches 22 are represented by shading in the plan view shown in FIG. 2B. After underetching of the buried oxide 20, the flexer 12 is exposed except for the anchor area and can be deflected, and can preferably be pivoted. Before or after these process steps for forming the flexer 12, the heating loop 4, the first spring element 2, a switching contact 16 and the electrical conductors 13, 14, 15 are produced on the second plane 18 using known methods, preferably electrochemically. The first spring element 2 is fitted at a first point 10 and can be moved freely at another point, for example an opposite point. The second spring element 12 is connected to the first spring element 2 at the point 10. Partial etching of the electrically insulating material 20 results in a separation from the substrate 11 being formed, as a result of which the second spring element 12 can move with respect to the substrate 11. The electrically insulating holder 5 and the end holder 8 are produced, for example, by means of photoresist, epoxy, polymer or materials containing oxide or nitride. The major details of the production methods according to the invention will be described further below.

The first spring element 2 has metal when the electrical signal to be switched is intended to be passed via the electrical conductor 15 to the switching contact 16. Otherwise, the first spring element 2 may also be composed of a semiconductor or a non-conductor.

The symbolically illustrated electrical conductor 15 connects the first spring element 2 to an electrical conductor on the rigid surface of the SOI layer 21. This conductor 15 is produced, for example, electrochemically on a sacrificial layer which bridges the trench 22. In order to achieve mobility, the conductor 15 may be formed in a meandering shape at least in the area of the bridge. The electrical conductors 13 and 14 are located at the third anchor point 26 of the heating loop 4 on an electrically insulating layer. Because these anchor points are fixed points, there is no need for movable electrical conductors here.

On thermal actuation, the actuator is deflected in the direction of the deflection arrow 7. The first spring element 2, which is located on the second plane 18, is in this embodiment made sufficiently broad that it is possible, to a first approximation, to preclude bending parallel to the surface of the substrate. The spring constant of the first spring element 2 is therefore greater than the spring constant of the second spring element 12.

Virtually all of the bending takes place in the area of the second spring element or flexer 12, which is composed of the material of the first plane 17, which is formed by the layer 21. When a substrate is in the form of an SOI wafer, this material is silicon, which is stable in the long term. This actuator is therefore excellently suitable for producing thermally actuated microswitches.

FIGS. 3A and 3B show a second embodiment of an actuator according to the invention. The raw material for producing this actuator is once again an SOI wafer. The flexer 12 and the other spring elements of the actuator are likewise produced as described in the example in FIGS. 2A and 2B. The functions are also comparable. In contrast to the actuator 1 described above, the flexer 12 is composed predominantly of silicon, with a small portion of metal. The connecting point of the electrical conductor 15 can therefore be moved to the area of the third anchor point 26, which means that this conductor 15 need not absorb any movement on actuation. The cross section of this metallization of the flexer 12 is matched to the electrical requirements of the signal current 24 to be carried. This generally requires only a very small conductor cross section. The characteristics of this flexer 12 are therefore essentially also governed only by the material of the first plane 17, that is to say by the silicon of the SOI layer.

The structures of the structural elements are not shown to scale in all the FIGS. For example, a flexer 12 composed of silicon has a height of at least 10 μm and a width at the narrowest point of at most 15 μm. In the case of the second spring element 12, particularly when using monocrystalline silicon, edges of the spring element are preferably not structured along the major axes of the crystal structure, in order to reduce the susceptibility to fracture.

The heating loop may have a width of 4 μm to 8 μm, preferably 5 μm, and a thickness of 10 μm to 15 μm, preferably 12.5 μm. The first spring element 2 may also have the same metal thickness, particularly in the situation when the metal of the spring element 2 is produced in the same method step as the metal of the spring element 3. The distance between the spring elements 2, 3 and the surface of the SOI layer may, for example, be 1 μm. A greater distance, preferably of for example 3 μm to 8 μm, preferably 4 μm, is preferable for electrical insulation, reducing capacitive scattering effects or for providing sufficient space for vertical bending. The electrical structural elements of the actuator may be separated by the same amount, for mutual electrical isolation. The thickness of the oxide layer 20 on the SOI wafer is subject to the same constraints as the thickness of the sacrificial layer for the first spring element. Layer thicknesses of 1 to 5 μm, preferably 3 μm, may be used here. After underetching, this is then the distance between the flexer 12 and the surface of the substrate 11 located underneath it. The actuators according to the invention may also be produced with dimensions which differ significantly from the typical dimensions mentioned above. The first spring element 2 may also be clamped in at both ends, such that deflection is achieved only in the central area, see FIG. 8.

In the figures, the flexers 12 are illustrated as being rectangular in a plan view. In order to prevent fracture points, the cross-sectional transition can be designed to be preferably smooth rather than stepped. Instead of being an arm extending longitudinally, the first spring element 2 may be in the form of a beam, as is illustrated in FIGS. 2A and 2B, or else in the form of a comb, see FIG. 9A, a plate with or without a recess, see FIG. 9B, or a spiral, see FIG. 9D. A meandering shape, see FIG. 9C, is also possible. These are only examples which are intended to indicate that different geometries can be provided for the individual spring elements, depending on the application of the actuator.

FIG. 4A shows a microswitch 23 which is formed by a vertically illustrated actuator 1 and a horizontally illustrated actuator 1, with both actuators being in the electrical OFF switching state. No contact is made in the area of the switching contacts 16. The actuation is switched off. The actuators 1 are designed according to the first embodiment of the invention, see FIGS. 2A and 2B.

In FIG. 4B, the two actuators 1 and/or the microswitch 23 are in the ON switching state. The actuation is likewise switched off. The transitions from OFF to ON and back take place in steps, with the steps taking a few milliseconds. The step sequence is specified in the following text.

Switching from OFF to ON:
Step 1 Actuation of the vertically illustrated actuator.
Step 2 Actuation of the horizontally illustrated actuator.
Step 3 Deactuation of the vertically illustrated actuator. The deflection is restored completely by the mechanical bending stress.
Step 4 Deactuation of the horizontally illustrated actuator.

The deflection is cancelled out only partially. The switching contacts 16 of the two actuators 1 remain hooked, as is illustrated in FIG. 4B. The horizontally illustrated flexor 12 holds the mechanical stress which is required to produce and maintain the contact force at the switching contacts 16.

The thermal actuation is not active in either of the two switching states. The active element in the ON switching state is the flexer 12, whose characteristics ensure the required contact force and therefore the contact reliability even over a very long switched-on time.

Switching from ON to OFF:
Step 5 Actuation of the horizontally illustrated actuator.
Step 6 Actuation of the vertically illustrated actuator.
Step 7 Deactuation of the horizontally illustrated actuator. The deflection is completely restored.
Step 8 Deactuation of the vertically illustrated actuator. The deflection is completely restored.

FIGS. 5A to 5D each show a side view of an SOI wafer and the major process steps for producing an actuator according to the first embodiment of the invention, although a third spring element 3, in the form of a heating loop, is not shown. The FIGS. likewise do not show the process steps which are known and required, such as deposition of starting layers, photolithographic structuring by means of photoresist, exposure and stripping as well as rinsing and drying between the process steps.

In the first process step, see FIG. 5A, the outlines of the flexer 12 are formed in the SOI layer 21 in the commercially available SOI wafer 19 as recesses or trenches 22, preferably on three sides, that is to say exclusively the connection side to the anchor area. The outlines can be formed, for example, by DRIE etching (Deep Reactive Ion Etching). These trenches 22 are then filled with a filler, preferably with a silicon material or oxide material 20, with the filling process being followed by planarization of the surface, with subsequent deposition of a sacrificial layer 25 composed of metal, preferably by structured electrochemical deposition, on the first plane 17 above the trenches 22. Metals, such as copper, or polymers may also be used as filling material. The important factor is that the filling material, like the sacrificial layer 25 or the intermediate layer 20, can be removed selectively with respect to the other functional layers, in order to expose the movable elements. Filling and planarization offer the advantage that a closed and planar surface is available again for subsequent processes, once the geometry of the flexer 12 has been defined.

It is also possible first of all to delimit and to fill only one of the sides of the flexer 12 which move during use of the actuator from the non-moving area of the SOI layer 21 by etching. In this case, further delimiting takes place in a subsequent additional etching step, in which case these trenches are then not filled with oxide.

In the second process step, see FIG. 5B, a metal is, for example, electro-chemically deposited after structuring, and is used as the sacrificial layer 25. Among other metals, copper is suitable for this purpose. In the third process step, see FIG. 5C, the appropriately structured metallic structural elements of the actuator are electrochemically deposited on the sacrificial layer 25, in particular the heating loop 4, which is not illustrated, and the first spring element 2. The electrical conductors 13, 14 and 15 as well as the switching contact 16 can also be electrochemically deposited before or after this, if they are composed of a different material to the heating loop and the first spring element 2. This is generally the case. The switching contact 16 and the electrical conductors are preferably composed of gold or gold alloys such as gold-palladium, gold-nickel, rhodium, ruthenium, palladium, silver or of coatings of such materials. In order to prevent contact welding when using gold, oxides can also be incorporated in the gold, by additionally depositing nanoparticles. Nanoparticles such as these may be composed of TiO₂, Al₂O₃, cerium oxide, silicon oxide or of any other material which can be introduced in nanoparticle size in the electrolyte and can be incorporated in the layer. Nickel or nickel alloys, for example nickel manganese, nickel iron or nickel cobalt, is or are preferably used for the heating loop and for the first spring element 2.

In the fourth process step, see FIG. 5D, the sacrificial layer 25, the oxide from the trenches 22 and the buried oxide layer under the flexer 12 are removed successively. This is preferably done by etching or underetching the flexer 12. The flexer 12 can therefore move freely as far as the anchor point and the first spring element 2, as can the heating loop, which is not illustrated here. The flexer 12 is the micromechanical second spring element, which in this exemplary embodiment is composed completely of silicon.

FIGS. 5A to 5D show the most important method steps for the production of an actuator as shown in FIGS. 2A and 2B. The described method steps are equally applicable to the production of the actuator shown in FIGS. 3A and 3B. A corresponding situation applies to the description of the method steps shown in FIGS. 6A to 6D, which, as an example, show the production of the actuator as shown in FIGS. 3A and 3B. FIGS. 5A to 5D and 6A to 6D do not show the formation of the third spring element 3.

In order to reduce the resistance for the current flow through the flexer, a bypass composed of metal can preferably be applied in addition to the silicon element. It is possible to apply a metal structure directly to the silicon flexer, as a result of which the current can flow through the metal rather than through the silicon. The essential geometry of the flexer 12 need not be modified in this case. However, in order to reduce the mechanical influence of the additional metal layer on the flexer, the sacrificial layer 25 can be arranged above the silicon flexer, and the metal bypass can be applied to the sacrificial layer above the silicon flexer, in which case this is anchored such that, by virtue of its length, no mechanical reactions occur on the actual mechanical flexer spring element. The metal bypass is therefore located physically above the silicon flexer separated by the distance corresponding to the sacrificial layer thickness, but has no negative effect on the spring function resulting from mechanical creepage.

FIGS. 6A to 6D show method steps for production of an actuator as shown in FIG. 3. The outlines of the flexer 12 are exposed on three sides as trenches 22 except for the anchor area, for example by etching, see FIG. 6A. These trenches 22 are not filled, thus saving the filling process and the planarization step, in comparison to the method steps shown in FIGS. 5A to 5D. The sacrificial layer 25 is electrochemically deposited in the second method step, see FIG. 6B. In this case, the trenches 22, or parts of them which, for example, have a width of between 2 μm and 5 μm, preferably 3 μm, are bridged, and therefore closed on the surface. In the third method step, see FIG. 6C, the structural elements of the actuator which are composed of metal are produced electrochemically. When different metals are used, this is done successively with the appropriate electrolytes. The heating loop as well as the flexer 12 with the first spring element 2 attached to it are exposed in the fourth method step, see FIG. 6D, preferably by etching processes. These elements of the actuator can therefore move freely as far as their anchor points, with the flexer 12 forming the micromechanical second spring element which, in this embodiment, is predominantly composed of silicon and of metal located on it.

FIGS. 7A to 7D show a number of method steps for producing a third embodiment of an actuator. After the trench 22 which is produced in a first method step, see FIG. 7A, a sacrificial layer 25 is electrochemically deposited onto an SOI layer 21 in a second method step, see FIG. 7B. In contrast to the second method step illustrated in FIG. 6B, the sacrificial layer 25 is additionally also present in the left-hand area of the wafer 19 in the step shown in FIG. 7B, but in this case this layer is not connected to the layer 25 applied in the right-hand area of the wafer. This free space, which is annotated with the reference sign 27 in FIG. 7B, is filled with a metal in a third method step, see FIG. 7C, which metal is preferably also applied to the sacrificial layer 25, in order to produce a structural element for the actuator or the contact point.

In the arrangement illustrated in FIG. 7B, the sacrificial layer 25 does not extend as far as the outer left-hand edge of the wafer 19. This area, which is annotated with the reference sign 28, is likewise filled with metal in the third method step, such that the sacrificial layer in the left-hand area of the wafer is coated with metal on both edges of the sacrificial layer and on the upper face of the sacrificial layer. After the sacrificial layer 25 has been removed in a fourth method step, see FIG. 7D, a metal layer produced in the form of an inverted U is therefore formed in the left-hand area of the wafer. This metal layer represents a bypass 29 which is connected only at its edges to the SOI layer 21 which is arranged underneath and forms the second spring element 12. Because of the distance from the second spring element 12, the mechanical reaction of the bypass 29 on the second spring element 12 is less than in the case of a metal layer deposited over the entire area. This is the case in particular when the geometry of the bypass is designed such that its spring constant is lower than that of the spring element 12. In the simplest case, the bypass has essentially the same geometry as the spring element 12, with the only difference being that the tapered beam is longer, and is connected to the SOI layer in an extension to the anchor point 26, in the area 28 which forms an anchor point. The bypass may have any other design geometry, for example in the form of a beam element or a meandering or spiral shape. The advantage of the lack of creepage in the second spring element 12 is thus essentially retained, despite the metal bypass 29.

If a current is intended to flow through the first spring element 2, this can be supplied at a connection 15, with this connection being located at the left-hand outer edge of the bypass 29 in the arrangement illustrated in FIG. 7D. The current passes this bypass 29 and enters the first spring element 2 at a connection point 30. By way of example, the current can be passed on via a contact element from this spring element.

### LIST OF REFERENCE SYMBOLS

1 Actuator
2 Cold arm; first spring element
3 Hot arm; third spring element
4 Heating loop
5 Holder
6 Reversal point
7 Deflection, deflection arrow
8 End holder
9 First anchor point
10 Second anchor point
11 Substrate
12 Flexer, taper; second spring element
13 Electrical conductor for actuation
14 Electrical conductor for actuation
15 Electrical conductor for the signal to be switched
16 Switching contact
17 First plane
18 Second plane
19 SOI wafer
20 Oxide layer, intermediate layer
21 SOI layer
22 Trench, recess
23 Microswitch
24 Signal current I
25 Sacrificial layer
26 Third anchor point
27 Free space in the sacrificial layer for the anchor point on the flexer 12
28 Free space in the sacrificial layer for the anchor point on the SOI layer 21
29 Bypass
30 Connection point

1-12. (canceled)

13. A micromechanical actuator, comprising:
a movable first spring element having metal and/or silicon, said first spring element being attached at a first point and freely movable at a second point;
a second spring element connected to the first spring element and having silicon;
an electrically insulating material, on which the second spring element is partially arranged;
a substrate to which the electrically insulating material is applied, wherein the second spring element is arranged at a distance from the substrate above the substrate on a first plane, and wherein the first spring element is arranged above the second spring element on a second plane at a distance from the first plane such that the first and second spring elements are movable with respect to the substrate; and
a third spring element mechanically coupled to the first spring element and constructed to induce an elastic deformation of the second spring element by a change in length.

14. The actuator of claim 13, wherein the second spring element, the electrically insulating material, and the substrate are formed from a composite substrate.

15. The actuator of claim 14, wherein the composite substrate is an SOI wafer, and the second spring element is an SOI layer.

16. The actuator of claim 13, wherein the electrically insulating material has an oxide layer.

17. The actuator of claim 13, wherein the substrate has a monocrystalline silicon.

18. The actuator of claim 13, wherein the third spring element has silicon and/or metal and is arranged on the second plane.

19. The actuator of claim 13, further comprising a metallic element arranged at a distance from the second spring element and is connected to the first spring element such that an electric current can be transported through the metallic element from a first anchor point to a second anchor point, which is arranged on the first spring element, in order to form a bypass for the second spring element.

20. The actuator of claim 19, wherein the metallic element is arranged above the second spring element.

21. The actuator of claim 19, further comprising a sacrificial layer provided between the metallic element and the second spring element.

22. The actuator of claim 19, wherein the metallic element has a spring constant which is lower than a spring constant of the second spring element.

23. The actuator of claim 13, wherein the second spring element has a height of at least 10 micrometers and a width of at most 15 micrometers.

24. The actuator of claim 13, for use as an electrical switch.

25. A method for producing an actuator, comprising the steps of:
providing a substrate having a layer located thereon composed of an electrically insulating material and a layer located thereon which has silicon and is arranged on a first plane;
forming a recess in the layer having silicon on the first plane;
bridging the recess with an electrochemically deposited sacrificial layer;
structured electrochemical deposition of an additional layer above and to the side of the sacrificial layer;
partially removing the sacrificial layer by etching to form first, second and third spring elements; and
forming at least one electrically insulating holder to connect the first spring element to the third spring element.

26. The method of claim 25, wherein the filler includes a silicon material or oxide material.

27. A method for producing an actuator, comprising the steps of:
providing a substrate having a layer located thereon composed of an electrically insulating material and a layer located thereon which has silicon and is arranged on a first plane;
forming a recess in the layer having silicon on the first plane;
filling the recess with a filler;
leveling a surface of the filler;
depositing a sacrificial layer of metal on the layer having silicon on the first plane above the recess;
structured electrochemical deposition of an additional layer above and to the side of the sacrificial layer;
partially removing the sacrificial layer and the filler by etching to form first, second and third spring elements; and
forming at least one electrically insulating holder to connect the first spring element to the third spring element.

28. The method of claim 27, wherein the depositing step includes the step of structured electrochemical deposition.

29. The method of claim 27, wherein the filler includes a silicon material or oxide material.
